(19) United States
(12) Patent Application Publication
(10) Pub. No.: US 2024/0298415 A1
(43) Pub. Date: Sep. 5, 2024

(54) Electrical Control Console for Watercraft

(71) Applicant: Christopher Donald LACKEY, Helotes, TX (US)

(72) Inventor: Christopher Donald LACKEY, Helotes, TX (US)

(21) Appl. No.: 18/541,879

(22) Filed: Dec. 15, 2023

Related U.S. Application Data
(60) Provisional application No. 63/449,347, filed on Mar. 2, 2023.

(51) Int. Cl. H05K 5/02; B60K 35/50; H01H 9/02

(52) U.S. Cl. CPC H05K 5/0243; B60K 35/50; H01H 9/02; B60K 2360/688; B60K 2360/691; B60K 2360/84

(57) ABSTRACT

An electrical/electronic control console capable of controlling electric devices installed in certain watercraft. The new console is designed with a specific shape and dimensions to facilitate mounting in the same position in the dash as the watercraft's original touch screen human machine interface (HMI), thereby serving as a replacement, or in alternate cases a redundant control device. In one embodiment, the console provides an array of analog switches operable with existing devices on the watercraft. In a second embodiment, the console provides an enclosure and platform for securing an off-the-shelf touchscreen tablet computer. Each embodiment also has a mounting system consisting of brackets and studs that allow for the attachment of the housing to the watercraft's dash.

### CROSS REFERENCES TO RELATED APPLICATIONS

This application claims the benefit under Title 35 United States Code § 119(e) of U.S. Provisional Patent Application Ser. No. 63/449,347; Filed: Mar. 2, 2023; the full disclosure of which is incorporated herein by reference.

### BACKGROUND OF THE INVENTION

### 1. Field of the Invention

The present invention relates generally to electrical control consoles for vehicles. The control console of the present invention has application as a backup or replacement control device intended for installation in certain pleasure watercraft models that are broadly owned throughout the US and globally.

### 2. Description of the Related Art

The market segment of pleasure watercraft having features that enable participation in wakeboarding and wake-surfing sports has rapidly grown in the last twenty years. During the same time frame, control systems installed in these watercraft began featuring touch screen human machine interfaces (HMIs). In the normal course of operating the watercraft, users activate and deactivate virtual buttons in the touch screen HMI to operate various onboard devices including ballast fill and drain pumps, bilge pumps, blowers, navigation lights, anchor lights, interior lights, dash lights, docking lights, flood lights, underwater decorative/ambiance lights, wake enhancement devices, ignition circuits, engine starters, heaters, audio controls, and other devices. The devices typically operate with 12 volt direct-current (DC) circuitry.

Many owners of watercraft with touch screen HMIs have reported that the devices fail in a variety of modes. A frequent description of failure is the separation of the exterior glass surface of the touch screen from the internal display with the touch reception capability. This failure results in users losing the ability to control many and ultimately all of the onboard devices that are intended to be controlled by using the touch screen HMI. To regain control and function of onboard equipment, replacement in-kind of the touch screen HMI has been the only commercially available option. New equipment replacement parts have been inadequate to fulfil the demand by high numbers of watercraft owners with failed touch screen HMIs.

### SUMMARY OF THE INVENTION

The present invention comprises an electric control console capable of controlling electronic and electrical devices installed in certain watercraft. The console of the present invention is designed with specific shapes and dimensions to facilitate mounting in the same position in the dash as the watercraft's original touch screen HMI, thereby serving as a replacement, or in alternate cases a redundant control device. Many general purpose switch enclosures are commercially available, though none contain the specific features combined in the present invention, and none adequately address the problem of replacing a touch screen HMI of specific dimensions to result in a precise fitment to the watercraft. In one embodiment of the present invention, a protrusion around the front perimeter of the device is provided that enables a cosmetic bezel to be attached and retained on the housing. This embodiment also has a mounting system consisting of a bracket and studs that allow for the attachment of the housing to the watercraft's dash. Finally, this embodiment has a surface recessed from the forward profile of the housing where a cosmetic faceplate is attached, thus providing identification text or symbols for mounted switches and thus concealing the housing's core structure.

An alternate embodiment of the switch console of the present invention takes the form of a panel having specific height and width dimensions to facilitate its installation from the rear side of the dash. The height and width dimensions are limited in extent to prevent physical interference with dash components, which would prevent the housing from mounting flush against the dash opening that is provided in the watercraft's dash. The height and width measurements are also of a minimum extent so that when installed, no gaps appear between the housing and the edges of the watercraft's dash opening. The mounting system of this embodiment consists of two holes of a specific diameter and spacing allowing the housing to be secured onto studs. The shape of the mounting holes may alternately take the form of slots that enable adjustment of the panel's position in the vertical and/or horizontal directions. A cosmetic face plate with switch identification labels in the form of text or symbols is mounted on the switch housing panel. An alternate embodiment does not have a face plate mounted on the panel, and has either a blank surface, or has switch identification markings present on the front surface of the panel.

All embodiments of the new switch console contain an array of electrical switches that are mounted on a panel or enclosure. The number of switches included, the specific type of switches included, and the specific devices controlled by the switches may vary. Each of the switches has one ‘source’ wire that is connected to a power source and one ‘load’ wire that carries electric current only when the switch is activated. The source and load wires are intended to be connected to specific existing wires and electronic/electrical circuit panels within the watercraft. The connections of the source and load wires to watercraft wiring may be accomplished either by means of a splice style connection or by using commercially available plug and socket style connectors.

### BRIEF DESCRIPTION OF THE DRAWINGS

Some embodiments of the present invention are illustrated as an example and are not limited by the figures of the accompanying drawings, in which like references may indicate similar elements and in which:

FIG. 1 depicts a perspective view of the front surface of one example of the electric switch housing comprising the electric control console according to various embodiments of the present invention.

FIG. 2 depicts a perspective view of the rear side of one example of the electric switch housing comprising the electric control console according to various embodiments of the present invention.

FIG. 3 depicts one example of a faceplate that may be installed on the front platform of the electric switch housing example shown in FIGS. 1 & 2. The faceplate features an aesthetic finish, holes for the mounting of electric switches, and text and/or icons to identify the mounted switches.

FIG. 4 depicts an exploded assembly view of the mounting system incorporated into one embodiment of the electrical switch housing comprising the current invention. The alignment lines shown indicate the path that components are compressed along, as the switch housing is inserted through the dash opening and the bracket is used to clamp the switch housing to the dash.

FIG. 5 depicts a detailed perspective view showing the raised trapezoidal profile that is attached to the front surface of an exemplary embodiment of the electric switch housing that comprises the current invention. The trapezoidal profile serves as a latching point for the attachment of a cosmetic bezel that surrounds the front surface of the switch housing.

FIG. 6 depicts an alternate exemplary embodiment of the switch mounting platform component of the current invention. The alternate switch mounting platform takes the form of a panel that is designed to be mounted on the rear side of the dash, and span across an opening provided in the dash of the watercraft.

FIG. 7 depicts an exemplary embodiment of the electrical system comprising the electric control console of the present invention. The lines 33a & 33b indicate the electrical interface between the control console and certain existing circuits in the watercraft.

FIG. 8 depicts a perspective view of the front surface of one example of the housing enclosure comprising a tablet mount control console according to an alternate embodiment of the present invention.

FIG. 9 depicts a perspective view of the rear side of the example of the housing enclosure comprising a tablet mount control console according to the alternate embodiment of the present invention shown in FIG. 8.

FIG. 10 depicts an exploded assembly view of the mounting system used with the embodiment of the housing enclosure comprising the tablet mount control console according to the alternate embodiment of the present invention shown in FIGS. 8 & 9. The alignment lines shown indicate the path that components are compressed along, as the housing is inserted through the dash opening and the bracket is used to clamp the housing to the dash.

FIG. 11 depicts a perspective view of the electronics panel of the system of the housing enclosure comprising a tablet mount control console according to the alternate embodiment of the present invention shown in FIGS. 8-10.

FIG. 12 depicts a perspective view of a further example of an electric switch housing comprising the electric control console according to a further alternate embodiment of the present invention.

FIG. 13 depicts an exploded assembly view of the mounting and electrical connection systems incorporated into the embodiment of the present invention shown in FIG. 12. The alignment lines shown indicate the path that components are compressed along, as the switch panel is attached to the dash opening.

FIG. 14 depicts a further example of a faceplate that may be installed on the front platform of the electric switch housing of the type shown in FIGS. 1 & 2. The faceplate features an aesthetic finish, holes for the mounting of electric switches, and text and/or icons to identify the mounted switches.

FIGS. 15A & 15B depict additional examples of faceplates that may be installed on the front platform of the electric switch housing of the type shown in FIGS. 1 & 2. These faceplates each feature an aesthetic finish, holes for the mounting of electric switches, and text and/or icons to identify the mounted switches.

### DETAILED DESCRIPTION OF THE EXEMPLARY EMBODIMENTS

The terminology used herein is for the purpose of describing particular embodiments only and is not intended to be limiting of the invention. As used herein, the term “and/or” includes any and all combinations of one or more of the associated listed items.

The present disclosure is to be considered as an exemplification of the invention and is not intended to limit the invention to the specific embodiments illustrated by the figures or descriptions below.

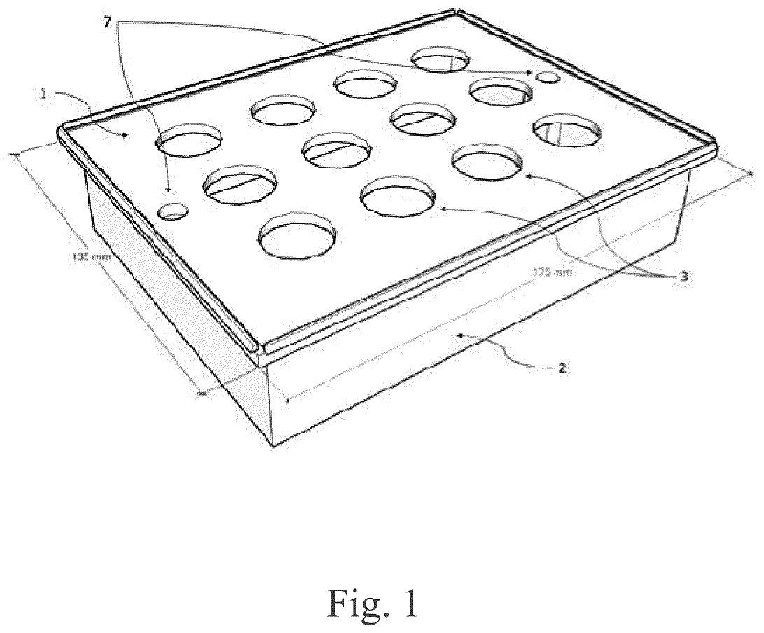

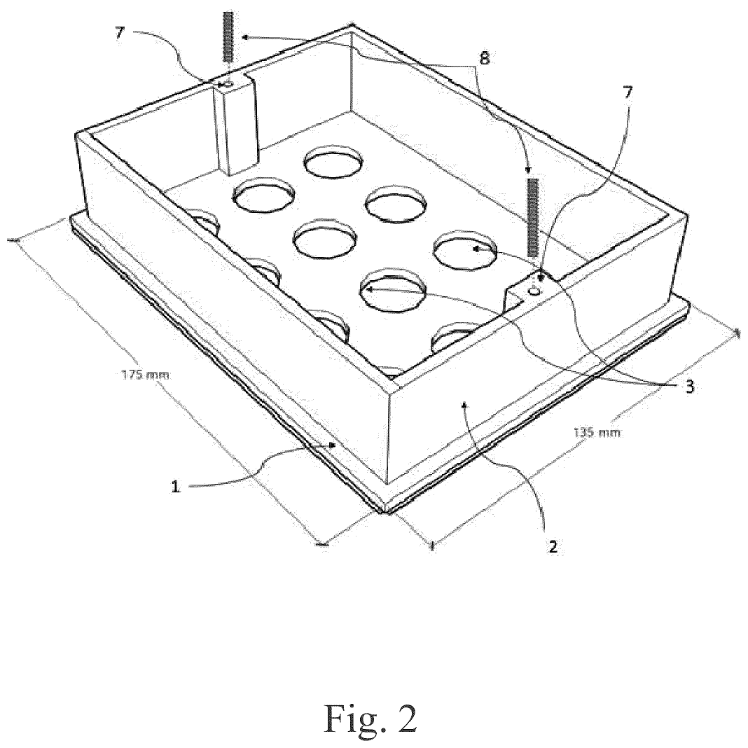

The present invention will now be described by referencing the included figures representing certain exemplary embodiments. One exemplary embodiment, referred to herein consists of a box style housing that is presented in FIGS. 1-6. The housing is preferably constructed using polylactic acid plastic by means of injection molding or 3D printing processes. The housing may also be constructed of any other material that can be shaped into the form of the housing and using any process capable of generating the shaped housing. The box style housing has five main functions. The first function is to mount to a dash opening of certain watercraft having specific measurements, such that it covers the entire area of the opening comprised of the width and height of the dash opening, without passing through and falling through the opening. To facilitate the first function, the box style housing consists of a front platform 1 (see FIGS. 1 & 2) and an internal rectangular box 2 (see FIGS. 1, 2, and 4) consisting of four walls. FIG. 2 shows a perspective view of the rear of the console. The width and height of rectangular box 2 measure less than the dash opening of 165+/−5 mm long by 125+/−5 mm wide, resulting in the ability of the box to slide into the dash opening. To exemplify the box style housing, FIG. 1 represents a box sized to fit a dash opening measuring 165 mm long by 125 mm wide. The width and height of the box may preferably be incrementally less than the dash opening's respective measurements by variable lengths in alternate embodiments. The width and height of the front platform measurements (175 mm by 135 mm as shown in FIGS. 1 & 2) are longer than the same measurements of the dash opening, and therefore the front surface 1 of the box style housing will not pass through the dash opening.

The second function of the box style housing is to provide a mounting surface 1 for electric switches. The mounting surface may be configured to hold switches of various sizes and shapes, such that there may be openings 3 that are circular, square, rectangular, oval, or any other shape present within the mounting surface. There may be any number of openings provided in the mounting surface.

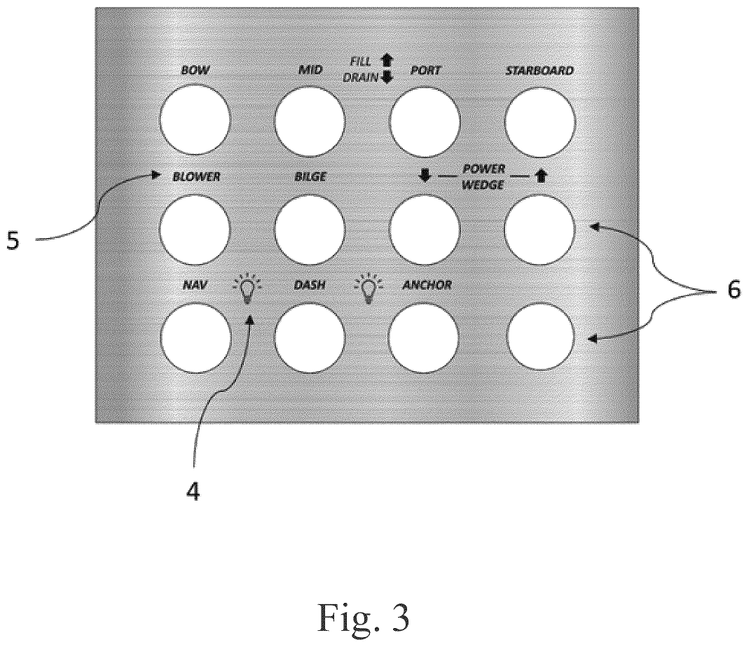

The third function of the box style housing is to provide text and/or icon labeling to identify the switches. In an exemplary embodiment of the box style housing, a recessed front surface 1 is provided to serve as a bed to hold a cosmetic face plate (see FIG. 3). The cosmetic face plate features an aesthetic appearance and has switch identifying icons 4 (see FIG. 3) and/or text 5 engraved or printed on its front surface (see FIG. 3). The face plate also has holes 6 (see FIG. 3) for mounting switches that in some embodiments align to the holes 3 (see FIGS. 1 & 2) provided on the top surface of the switch housing front platform 1 (see FIG. 1). In alternate embodiments of the box style housing, switch identification markings may be absent, may appear directly on the switches, or may appear directly on the front surface of the box style housing.

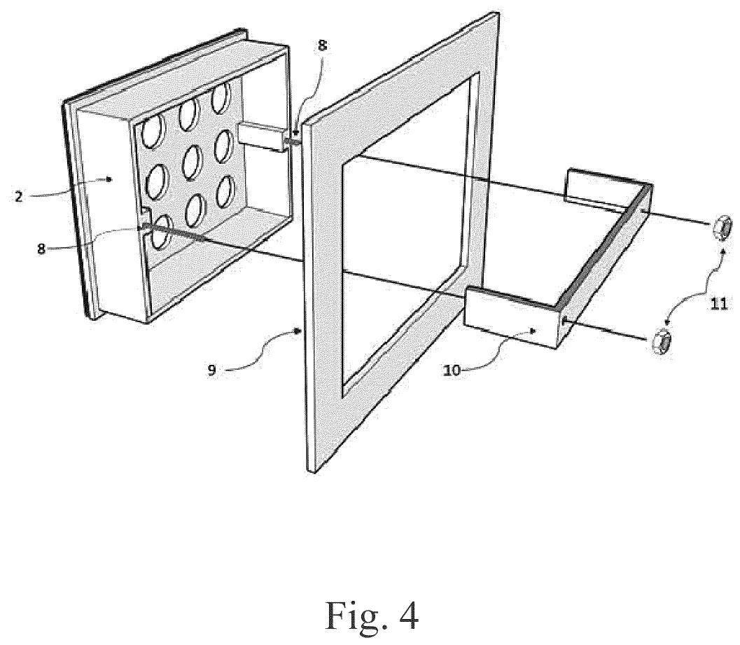

The fourth function of the present invention is to provide a mechanism to facilitate the secure mounting of the switch housing to the dash. The box style housing contains two holes 7 (see FIGS. 1 & 2) within the walls forming the rectangular box 2 (see FIG. 2). Two machine screws 8 are mounted in the holes to serve as attachment points for a bracket, as shown in FIG. 4. The assembly of the rectangular box 2 (see FIGS. 1, 2, and 4) into the opening in the dash 9 (see FIG. 4) is shown in an exploded view indicating how components are assembled. Once the rectangular box is positioned so that the front platform is flush against the front of the dash, bracket 10 is placed over the ends of the machine screws 8. Threaded nuts 11 are threaded onto the machine screws 8 and tightened. Tightening the nuts results in the bracket clamping the front platform of the switch housing against the dash in the area adjacent to the dash opening, thereby firmly fastening the switch housing to the dash.

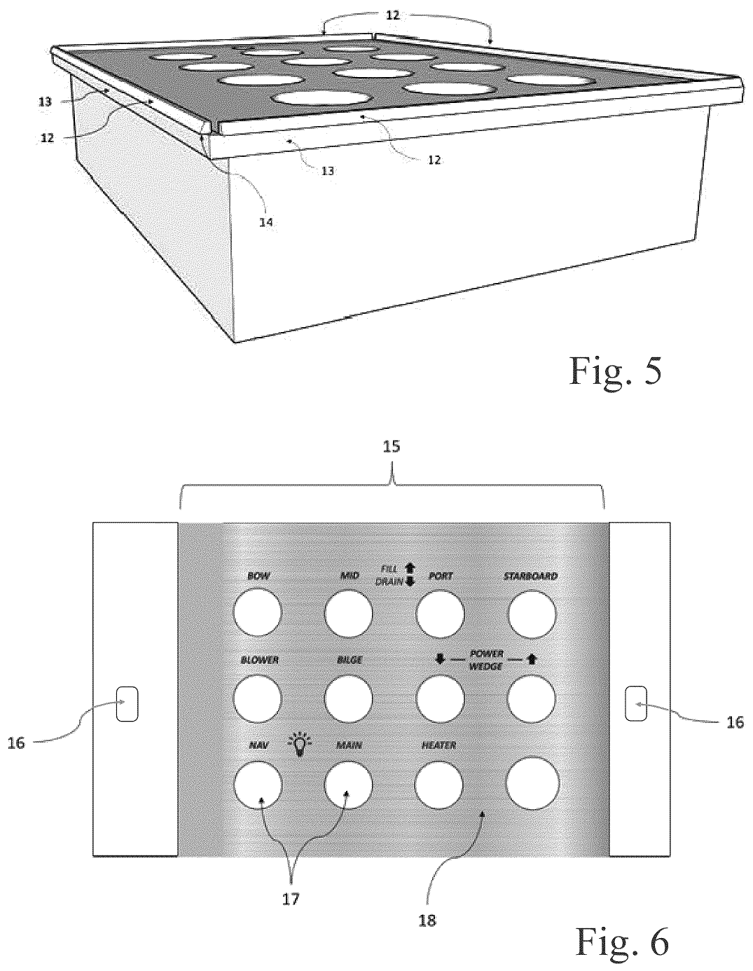

The fifth function of the box style housing embodiment of the present invention is to provide an attachment mechanism for a cosmetic trim bezel that is a detachable component of the touch screen human machine interface (HMI) supplied with certain watercraft. FIG. 5 illustrates the bezel attachment mechanism. The perimeter of the front surface of the box style housing includes a trapezoidal protrusion 12 running the full length of the housing's front platform sides 13. The outside corner 14 of the trapezoidal protrusion forms the outermost edge of the front surface of the box style housing. The outermost edge offsets the front platform to which the trapezoidal protrusion is attached by 0.5-1.0 mm, creating an overhang relative to the top surface. The overhang formed by the outermost edge creates a latch point that enables the attachment and retention of a cosmetic bezel. The cosmetic bezel has a clip (not visible in this view) that flexes slightly while the bezel is pressed onto the front of the box style enclosure. When the clip passes the outermost edge of the box style enclosure, the clip latches under the edge and the bezel is retained in position.

An alternate embodiment of the switch housing takes the form of a panel to which electrical switches are mounted, and which is intended to be mounted to the rear side of the dash, adjacent to the opening wherein the touch screen HMI originally appeared. A panel exemplifying the rear mounted switch panel is illustrated in FIG. 6. When the panel is mounted on the rear side of the dash, the middle portion of panel 15 spans across the dash opening and is visible through the opening when viewed from the watercraft operator's normal seated position. The length of the panel extends greater than length of the dash opening, which may typically measure 160 mm. The height of the panel extends greater than the height of the dash opening, which may typically measure 100 mm. The panel consists of holes or slots 16 used to facilitate mounting. The horizontal distance between holes 16 would measure 203+/−20 mm for a panel designed to fit the above described dash opening. The panel consists of holes 17 taking the form of any shape, within which electrical switches can be installed. The number of holes 17 for mounting switches may vary. The panel may further consist of a face plate 18 having a cosmetically aesthetic appearance and which may have markings or text to identify devices controlled by the switches. In embodiments of the switch mounting panel without having a face plate, switch identification markings or text may appear directly on the surface of the panel.

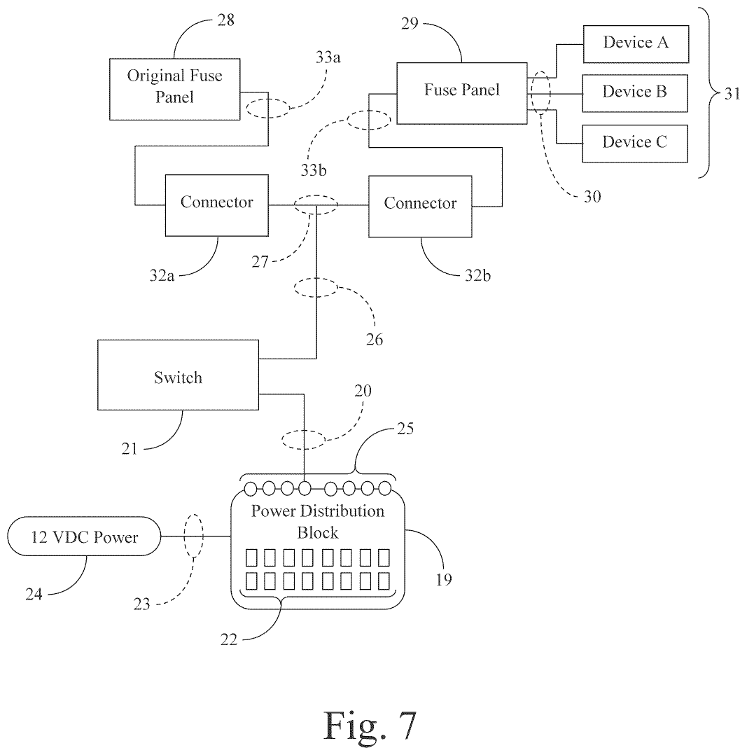

An exemplary embodiment of the current invention includes a power distribution block 19. FIG. 7 shows, in schematic form, the power distribution block and its associated wired connection 20 to a switch 21. The depicted switch represents multiple possible switches that may be installed in the electrical control console of the present invention. In the case of multiple switches, additional wired connections (not shown in this view) are made to the power distribution block 19, with wires running in parallel to the depicted wire. Power distribution block 19 contains fuses 22 to protect circuits to which it is connected from electrical overload. Power distribution block 19 has a main power lead 23 that is connected by a ring terminal 24 to a power lug on the watercraft that supplies 12 VDC electricity when the electrical control console of the present invention is installed in a watercraft. The power distribution block 19 also has several terminal attachment points 25, the exact number of which varies depending on the commercially available model selected, which distribute fuse-protected 12 VDC electricity to the switches mounted on the switch housing's front platform 1 (see FIG. 1), when connected by wire.

Each switch 21 (see FIG. 7) mounted on the electrical control console of the present invention consists of a +12 VDC source wire 20, which is connected to power distribution block 19, and a load wire 26 which supplies electricity to the end device when the switch is activated. The length of the +12 VDC source wire for each switch may vary according to user preference. In an exemplary embodiment of the current invention, each load wire originating from the control switch is terminated with a ‘T’ junction 27. The +12 VDC load wires 26 from the electrical control switches 21 included on the switch housing may consist of a variety of types and sizes of commercially available wire. The length of wire consisting of the +12 VDC load wire attached to each switch will be of sufficient length to reach the fuse panel belonging to the watercraft 28 and the existing wire harness associated with the fuse panel 29, typically 12-30 inches in length. The length may vary according to user preference. One outlet of ‘T’ junction 27 is intended to be connected inline with original existing +12 VDC supply wiring 30 in the watercraft that is connected to the end devices to be controlled by the electrical control console. The other outlet of ‘T’ junction 27 is intended to be connected to the original equipment fuse panel in the watercraft 28, which supplies electricity to the same end devices that are to be controlled by the electrical control console. When ‘T’ junction 27 is connected to the original equipment fuse panel 28, and the end device +12 VDC supply wire(s) 30, the wiring connection configuration described herein permits the end devices 31 consisting of pumps, lights, and the like, to be controlled by the watercraft's original computers and circuits while enabling redundant control of the end devices 31 by the electrical control console. The negative or DC ground for the electrical circuits described above is typically a ground buss on the watercraft that is connected to the negative terminal of the watercraft battery.

In cases where continued control over the end devices 31 by the watercraft's computers and circuits is not desired, the terminus of the switch load wire may be connected directly to the +12 VDC supply wire 30 of the end device instead of utilizing a ‘T’ junction. In this case, the watercraft's original fuse panel 28 is disconnected from the end device(s) and the electrical control console of the present invention has exclusive control of the circuit. All the connections described herein may be accomplished by common methods of connecting wiring, including by way of an attached commercially available connector represented by blocks 32, (see FIG. 7). Lines 33a & 33b shown in FIG. 7 indicate commercially available connectors 32 are attached to mechanically compatible connectors in the watercraft during installation of the electrical console of the present invention. In some embodiments of the current invention, multiple end devices may be controlled by the same electrical control switch. In such an embodiment, the +12 VDC supply wires for multiple end devices are joined and connected to the single +12 VDC load wire from one electrical control switch.

The electric switch console of the present invention is intended to be installed in certain watercraft that were manufactured with touch screen human machine interfaces (HMIs). When installed, the switch console provides either replacement or redundant backup control over certain electrical circuits of the watercraft. Certain touch screen HMIs are broadly known to fail, leading to an inability to control devices installed in the watercraft. In cases of touch screen HMI failure, when the electric control console of the present invention is installed, it allows restored control over the watercraft's devices. Typical circuits controlled by the console include water pumps, blowers, lights, a motor starter and ignition circuit, heaters, and wake shaping devices.

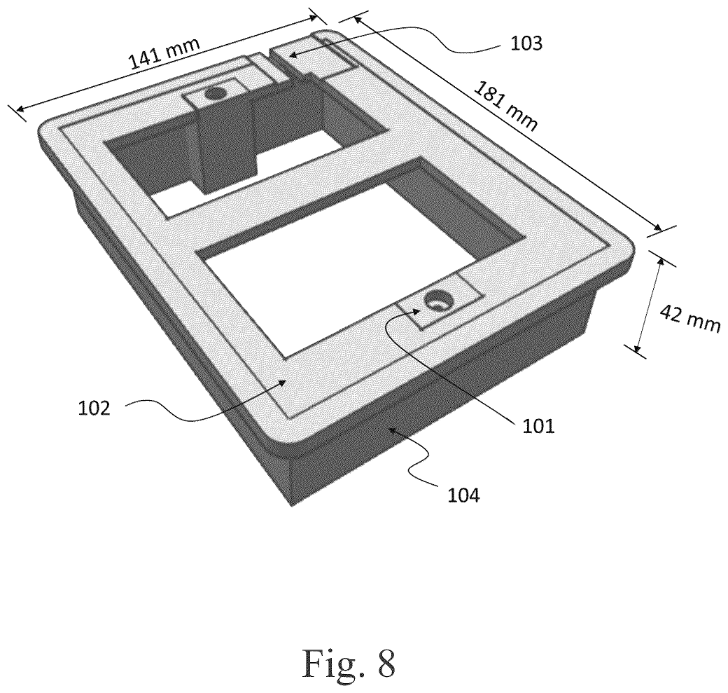

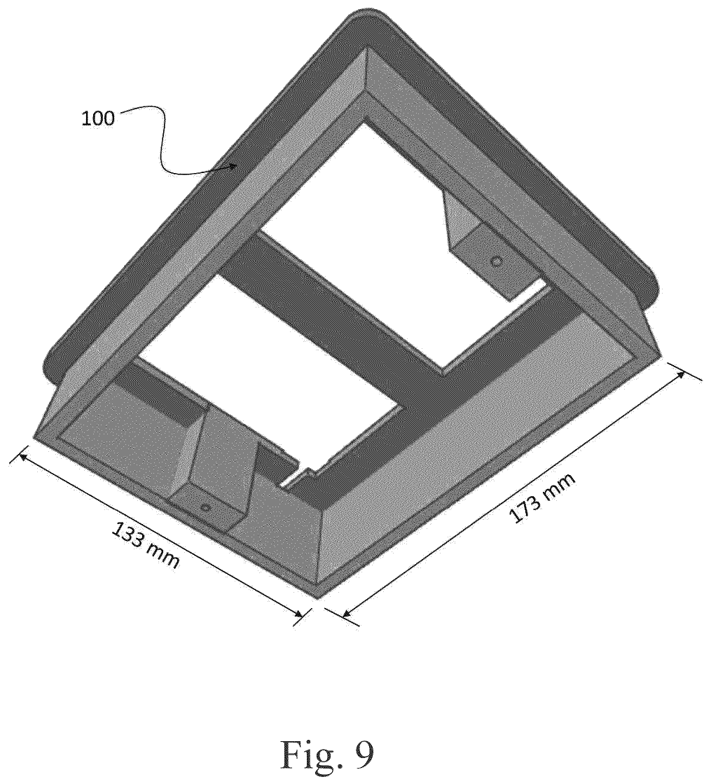

Reference is next made to FIGS. 8-11 for a detailed description of a tablet computer mount embodiment of the present invention. In this embodiment, the analog switches are replaced with a touchscreen computer tablet operating with an installed graphic user interface (GUI) and wirelessly connected to the balance of the system's control electronic. FIG. 8 depicts a perspective view of the front surface of one example of the housing comprising a tablet mount control console according to this alternate embodiment. In FIG. 8, the tablet mount is shown to include mounting stud receptacles 101, tablet mounting surface 102, charge cable channel 103, and dash alignment sleeve 104. FIG. 9 depicts a perspective view of the rear side of the enclosure housing 100 comprising the tablet mount control console according to the alternate embodiment of the present invention shown in FIG. 8.

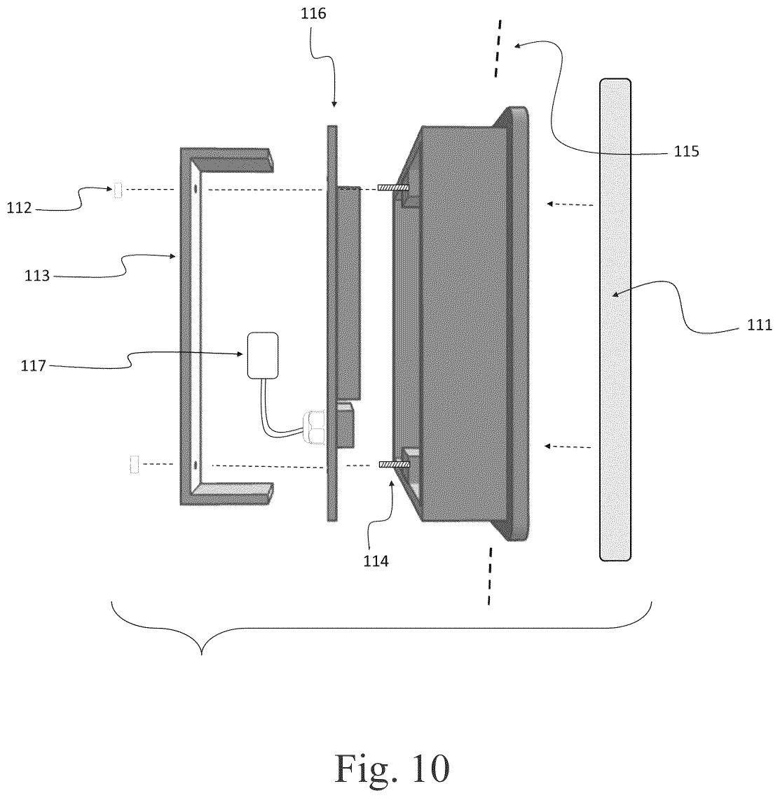

FIG. 10 depicts an exploded assembly view of the mounting system incorporated into the embodiment of the housing comprising the tablet mount control console according to the alternate embodiment of the present invention shown in FIGS. 8 & 9. The alignment lines shown indicate the path that components are compressed along, as the housing is inserted through the dash opening and the bracket is used to clamp the housing to the dash. In FIG. 10, the components are shown to include tablet 111 which is removably secured to the outward face of enclosure housing by any of a variety of means (magnetic, adhesive, edge clips, sleeve frame, etc.). The enclosure housing itself is secured through dashboard 115 (schematically represented with dashed lines) with fastening nuts 112, fastening bracket 113, and mounting studs 114. Electronics mounting panel 116 with connector 117 (Molex 33482 or similar) is secured in place between fastening bracket 113 and the enclosure housing and may preferably form the back of the assembled enclosure housing.

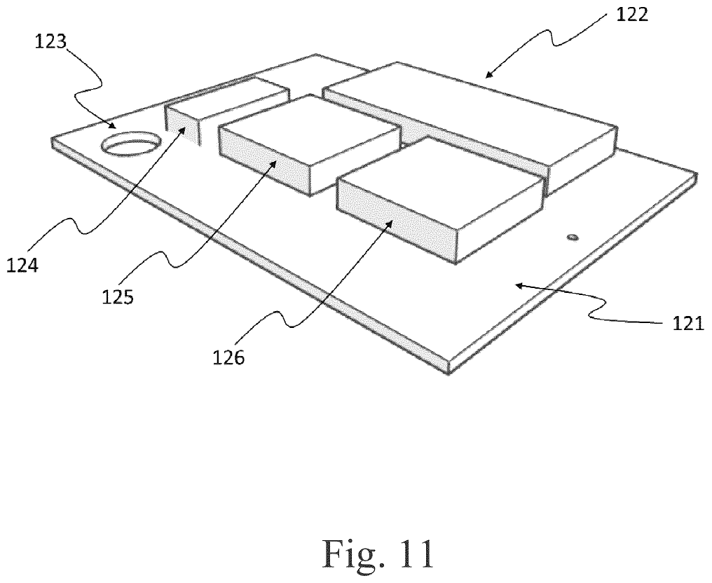

FIG. 11 depicts a detailed perspective view of the electronics panel of the system of the enclosure housing comprising a tablet mount control console according to the alternate embodiment of the present invention shown in FIGS. 8-10. In FIG. 11, electronics mounting plate 121 is preferably constructed from ⅜-inch thick acrylic and defines a cable pass-through 123 to accommodate the output device control wires (wiring harness). Microprocessor printed circuit board (PCB) 122 positioned on plate 121 is preferably an Arduino, Raspberry Pi, or similar microprocessor system that is programmed to work with the GUI on the attached tablet computer. Voltage regulator PCB 124 is also shown positioned on plate 121 as well as Bluetooth communication PCB 125 and CAN bus communication PCB 126. Bluetooth device components are well known in the art and are typically incorporated within tablet computers to provide short distance network communication. The Controller Area Network (CAN bus) is a message-based communications protocol designed to allow the electronic control units (ECUs) found in many vehicles and watercraft, as well as other devices, to communicate with each other.

At a minimum, tablet 111 and microprocessor 122 combine to provide digital switches in the form of power controls for the watercraft's various switchable devices. Expanded capabilities for the two digital processor components of the system are anticipated to include a wide array of watercraft sensors providing signal information back into the system of the present invention for use and/or display on the tablet screen. In addition, the programmable tablet lends itself to providing automated control (such as pre-programmed sequencing of switched devices) beyond the simple manual switching carried out with use of the tablet touchscreen.

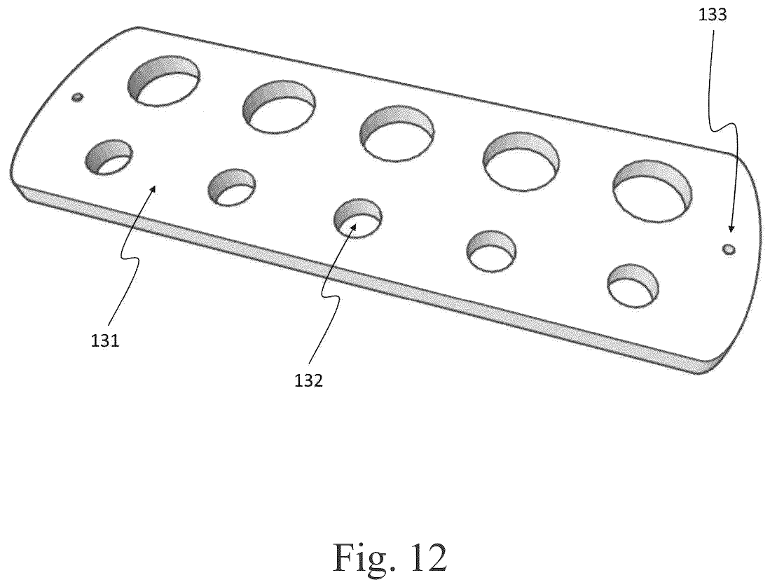

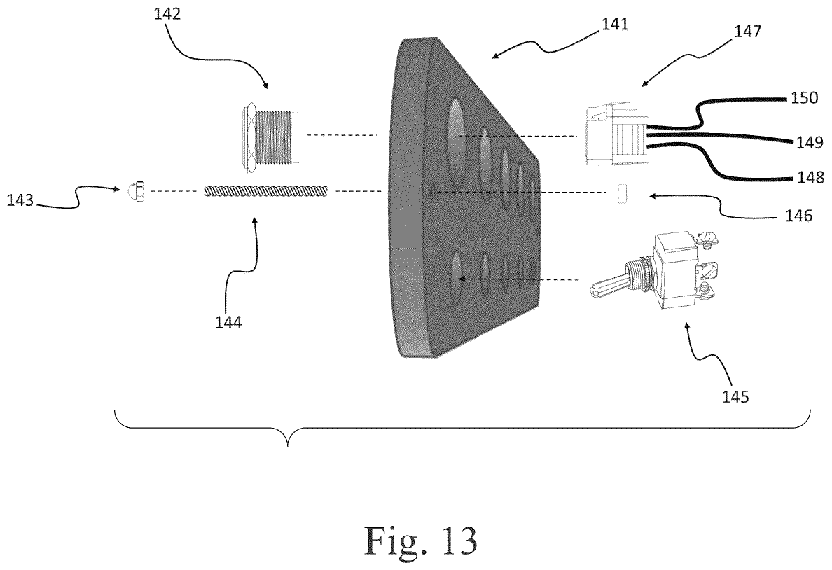

Reference is next made to FIGS. 12 & 13 for a detailed description of a further alternate embodiment of an analog switch version of the present invention. FIG. 12 depicts a perspective view of a further example of an electric (analog) switch housing comprising the electric control console according to a further alternate embodiment of the present invention. Similar in many respects to the system described above with respect to FIGS. 1 & 2, FIG. 12 shows a reduced size, limited functionality, version of the present invention applicable to many watercraft configurations. Faceplate 131 in FIG. 12 is preferably ⅜-inch or ¼-inch acrylic. An array of switch mounting holes 132 are shown along with a number of mounting stud holes 133. FIG. 13 depicts an exploded assembly view of the mounting system incorporated into the embodiment of the present invention shown in FIG. 12. The alignment lines shown indicate the path that components are compressed along, as the switch panel is attached to the dash opening. In FIG. 13, switch mounting panel 141 receives a number of push button style electric switches 142 connected to corresponding wire harness/wiring adaptors 147. In the typical installment, adaptor 147 would include wires for 12 VDC input 148, switch ground wire 149 (for incorporated LED), and output wire 150 typically with an attached female spade connector (combined with switch LED light input wire). Additional baton toggle style electric switches 145 are also installed through panel 141 and connected by retrofit wiring and/or a wiring harness.

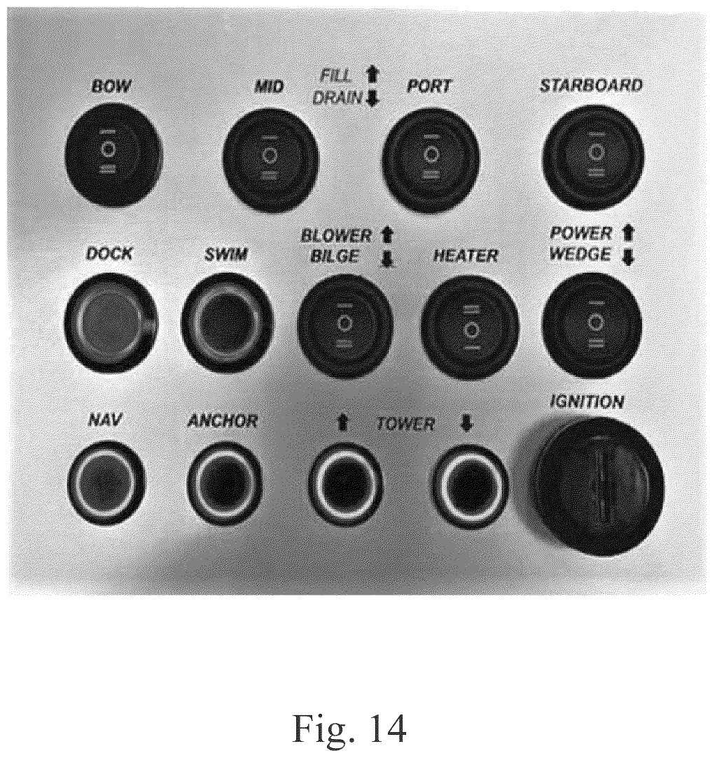

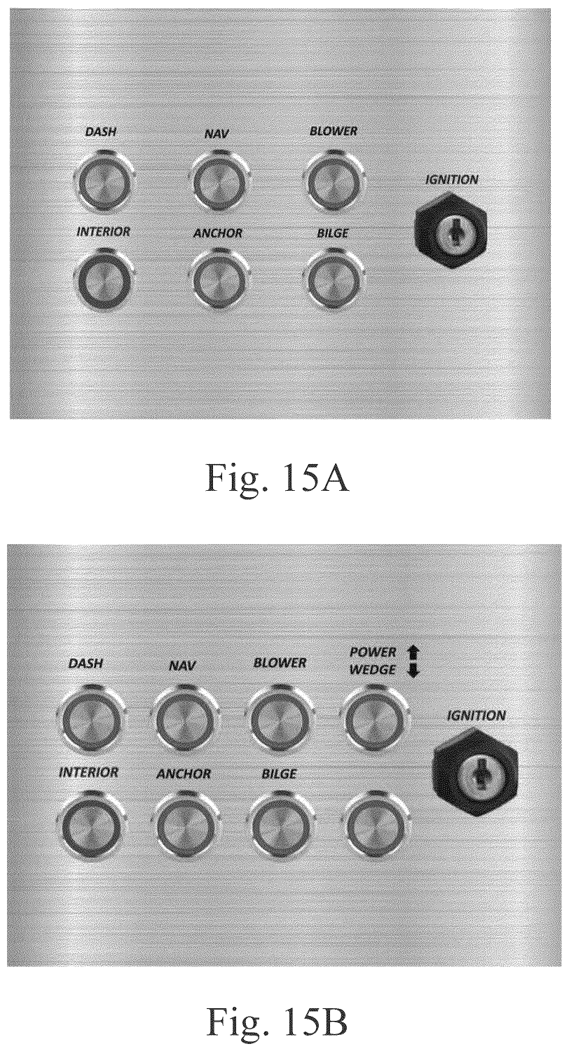

Reference is finally made to FIG. 14 and FIGS. 15A & 15B for additional examples of faceplates arranged for a few of the variety of operational controls associated with specific watercraft. FIG. 14 depicts a further example of a faceplate that may be installed on the front platform of the electric switch housing of the type shown in FIGS. 1 & 2. As with earlier examples, the faceplate features an aesthetic finish, holes for the mounting of electric switches, and text and/or icons to identify the mounted switches. FIGS. 15A & 15B depict additional examples of faceplates that may be installed on the front platform of the electric switch housing of the type shown in FIGS. 1 & 2. These faceplates also each feature an aesthetic finish, holes for the mounting of electric switches, and text and/or icons to identify the mounted switches.

Although the present invention has been described in conjunction with a number of preferred embodiments, those skilled in the art will recognize modifications to these embodiments that still fall within the spirit and scope of the invention. Because of the variety of watercraft that the system of the present invention could function with, the specific dimensions, aperture arrays, and attachment structures of the enclosures and panels will vary depending on the retrofit application. With the touchscreen tablet embodiment of the invention, a variety of GUIs may be programmed into the tablet and selected for operation based on the user's watercraft. Additionally, some aspects of the present invention may be implemented with the original manufacture of watercraft that are structured to accommodate the dimensions of one or more of the proprietary systems. Overall, the invention has been described in terms of a basic analog embodiment and a basic digital (tablet computer) embodiment with a number of add-on functionalities that may be implemented separately or collectively. Further add-on functionalities will be anticipated by those skilled in the art that do not depart from the spirit and scope of the invention as set forth in the appended claims.

I claim:

1. A supplemental or replacement electrical switch console comprising:
a switch housing and mounting panel measuring at least 160 mm×100 mm; and
the switch housing and mounting panel comprising a front platform with a perimeter profile edge that enables attachment of a cosmetic bezel;
wherein the switch housing and mounting panel is sized to be mounted through an existing dash opening.

2. The electrical switch console of claim 1 further comprising a bracket assembly attachable to the switch housing and mounting panel to secure the console within the existing dash opening.

3. The electrical switch console of claim 1 wherein the switch housing and mounting panel is mounted behind a dashboard and spans across an opening in the dashboard measuring approximately 160 mm×100 mm.

4. The electrical switch console of claim 1 further comprising a power distribution block and associated wiring to provide +12 VDC to one or more electrical switches positioned within the console.

5. The electrical switch console of claim 4 wherein the electrical switch console operates as supplemental control switches connected inline or in parallel with existing electrical control circuits in the watercraft.

6. A supplemental or replacement digital electronic switch console comprising:
a housing and mounting panel measuring at least 160 mm×100 mm, the housing and mounting panel comprising a front platform with a perimeter profile edge that enables attachment of a touchscreen tablet computer;
a circuit board panel positioned within the housing and mounting panel, the circuit board panel comprising: a microprocessor circuit; a voltage regulator circuit; a wireless digital communication circuit; and an output wiring harness;
wherein the housing and mounting panel is sized to be mounted through an existing dash opening.
